(19) United States
(12) Patent Application Publication
(10) Pub. No.: US 2002/0115019 A1
(43) Pub. Date: Aug. 22, 2002

(54) Photosensitive flexographic printing element having at least two IR-ablative layers

(76) Inventors: Jurgen Kaczun, Niederkirchen (DE); Sabine Philipp, Morfelden-Walldorf (DE)

Correspondence Address: Herbert B. Keil, KEIL & WEINKAUF, 1101 Connecticut Ave., N.W., Washington, DC, 20036, US

(21) Appl. No.: 09/998,237

(22) Filed: Dec. 3, 2001

(30) Foreign Application Priority Data
Dec. 7, 2000 (DE) 10061116.8

(51) Int. Cl. G03F 7/095; G03F 7/18

(52) U.S. Cl. 430/273.1; 430/945; 430/306; 430/271.1; 430/944

(57) ABSTRACT

A photosensitive flexographic printing element for the production of flexographic printing plates by digital imaging by means of lasers which comprises a combination of at least two different IR-ablative layers in which one layer comprises an elastomeric binder and the other comprises a self-decomposing binder. A process for the production of flexographic printing plates using an element of this type.

The present invention relates to a photosensitive flexographic printing element for the production of flexographic printing plates by digital imaging by means of lasers which comprises a combination of at least two different IR-ablative layers in which one layer comprises an elastomeric binder and the other comprises a self-decomposing binder. The invention furthermore relates to a process for the production of flexographic printing plates using an element of this type.

The conventional method for the production of flexographic printing plates by laying a photographic mask on a photopolymeric recording element, irradiating the recording element with actinic light through this mask and washing out the unpolymerized areas of the exposed element with a developer liquid is increasingly being replaced by CtP (computer-to-plate) technology, frequently also known as digital imaging. In CtP methods, the photographic mask in conventional systems is replaced by the masks integrated into the recording element.

Although a number of different methods have been proposed, only two have hitherto achieved significant importance in the market. In the first method, the photopolymerizable element is provided with a suitable ink receptor layer, and a mask is printed on by means of an ink-jet printer, as disclosed, for example, in WO 97/25206. The element can subsequently be exposed and developed in a known manner.

In the second method, the photopolymerizable element is coated with a substantially opaque, IR-ablative layer. Layers of this type usually comprise carbon black. Imagewise irradiation by means of a laser removes the IR-ablative layer at the points where it is hit by the laser beam, and the underlying photopolymerizable layer is uncovered. The image recording element can then be irradiated over its full area with actinic light through the ablatively formed mask in a known manner and washed out using a developer liquid. In the washing-out step, the nonablated residues of the IR-ablative layer and the underlying unpolymerized areas of the exposed element are removed.

Flexographic printing elements having IR-ablative layers are known in principle. EP-A 654 150 discloses a flexographic printing element having an IR-ablative layer. The IR-ablative layer comprises an IR-absorbent material. In addition, polymeric binders and a large number of different auxiliaries, for example dispersion aids or plasticizers, are disclosed as optional constituents. Furthermore, an additional barrier layer between the photopolymerizable layer and the IR-ablative layer is disclosed. This is intended to prevent diffusion of monomers from the photopolymerizable layer into the IR-ablative layer. EP-A 654 150 also discloses the fact that, in principle, more than one IR-ablative layer can be available.

EP-A 741 330 discloses an IR-ablative flexographic printing element which has no barrier layer of this type. A multiplicity of widely differing polymers is disclosed as binders for the IR-ablative layer. Furthermore, the IR-ablative layer may also comprise a second binder in a smaller amount, for which a multiplicity of widely varying polymers is likewise disclosed.

EP-A 908 778 discloses a flexographic printing element which has an IR-ablative layer comprising SIS or SBS block copolymers.

EP-A 767 407 discloses a flexographic printing element having an IR-ablative layer which has an elastomeric, film-forming binder. Binders disclosed are polyamides and polyvinyl alcohol polyethylene glycol graft copolymers.

In the process for the production of flexographic printing plates by IR ablation, the quality of the IR-ablative layer is the crucial parameter for the quality of the flexographic printing plate and the economic efficiency of the process. The IR-ablative layer must satisfy a number of widely varying quality criteria:

It should have high sensitivity to lasers in order to ensure rapid and complete removal of the layer with the lowest possible laser power.

It should be soluble in conventional wash-out agents for the photopolymerizable layer so that it can be removed together with the unpolymerized constituents of the layer during the conventional development step. Otherwise, two wash-out steps would have to be carried out.

The laser apparatuses used nowadays are usually instruments with rotating drums (external or internal drums). The IR-ablative layer must therefore be elastic in order that it does not tear or wrinkle on clamping onto the drums.

It must be tack-free in order that no dust is attracted which could interfere with the IR ablation.

For storage and transport, flexographic printing elements are usually protected against damage by means of a protective film, which has to be removed before the IR ablation. The protective film must have only low adhesion to the IR-ablative layer in order that the IR-ablative layer is not damaged on removal.

Conversely, the IR-ablative layer must adhere strongly to the light-sensitive layer in order that it is not removed at the same time on removal of the protective film and in order that no air bubbles nullify the advantage of direct contact between the IR-ablative layer and the photopolymerizable layer.

The person skilled in the art who would like to produce a high-sensitivity, high-quality flexographic printing element having an IR-ablative layer sees himself confronted with a typical catch 22 situation. In order to obtain an IR-ablative layer with the highest possible sensitivity, the use of a self-oxidative self-decomposing binder, such as nitrocellulose, is advisable. However, nitrocellulose layers are very brittle, and consequently the elasticity of nitrocellulose layers is unsatisfactory and flexographic printing elements of this type tear and wrinkle easily on clamping onto drum instruments. Although the brittleness can be reduced by addition of suitable plasticizers, the addition of plasticizers frequently has the consequence, however, of tacky layers with excessive cover film adhesion. However, typical tack-free binders, such as certain polyamides, have significantly lower sensitivity.

It is an object of the present invention to provide a flexographic printing element whose IR-ablative layer has the highest possible proportion of self-decomposing binders and yet satisfies the abovementioned requirements.

We have found, surprisingly, that this objective can be achieved by a combination of at least two different IR-ablative layers.

Accordingly, a photosensitive flexographic printing element for the production of flexographic printing plates for digital imaging by means of lasers has been found which comprises at least

a dimensionally stable support,

a photopolymerizable layer, at least comprising an elastomeric binder, a polymerizable compound and a photoinitiator or photoinitiator system,

at least two laser-ablatable layers A and B, each comprising at least one binder and also an IR absorber for laser radiation, and

optionally a removable, flexible protective film,

where the at least one binder of layer A is an elastomeric binder and the at least one binder of layer B is a self-decomposing binder, and the optical density of the entire layer sequence of IR-ablative layers in the actinic spectral region is at least 2.5.

We have also found a process for the production of flexographic printing plates using an element of this type.

In detail, the following comments should be made regarding the invention.

In the photopolymerizable printing element according to the invention, a conventional photopolymerizable layer, if desired with an adhesion layer, is applied to a dimensionally stable support. Examples of suitably dimensionally stable supports are plates, films and conical and cylindrical tubes (sleeves) made from metals, such as steel or aluminum, or plastics, such as polyethylene terephthalate (PET) or polyethylene naphthalate (PEN).

The photopolymerizable layer consists of a negative-working photopolymerizable mixture, i.e. one which is cured by exposure. This can be carried out by photocrosslinking with previously prepared polymers, by photopolymerization of low-molecular-weight, photopolymerizable compounds or both. Photopolymerizable layers essentially consist of a polymeric, elastomeric binder which can be washed out in the developer, an ethylenically unsaturated, free-radical-polymerizable compound, a photoinitiator or a photoinitiator system, and optionally further additives and auxiliaries. The composition of layers of this type is known in principle and is described, for example, in DE-A 24 56 439 or EP-A 084 851.

The elastomeric binder can be a single binder or a mixture of various binders. Examples of suitable binders are the known vinylaromatic-diene copolymers or block copolymers, for example conventional SIS or SBS block copolymers, diene-acrylonitrile copolymers, ethylene-propylene-diene copolymers or diene-acrylate-acrylic acid copolymers. Examples of suitable polymerizable compounds are conventional ethylenically unsaturated monomers, such as acrylates or methacrylates of mono- or polyfunctional alcohols, acrylamides or methacrylamides, vinyl ethers or vinyl esters. Examples include butyl (meth)acrylate, 2-ethylhexyl (meth)acrylate, butanediol di(meth)acrylate and hexanediol di(meth)acrylate. Suitable initiators for the photopolymerization are aromatic compounds, for example keto compounds, such as benzoin or benzoin derivatives.

The photopolymerizable mixtures may furthermore comprise conventional auxiliaries, for example inhibitors for thermally initiated polymerization, plasticizers, dyes, pigments, photochromic additives, antioxidants, antiozonants or extrusion aids.

The precise composition and thickness of the photopolymerizable layer is determined by the person skilled in the art depending on the particular requirements. It is also possible to employ a plurality of photopolymerizable layers of identical or different composition arranged one on top of the other. Furthermore, the element may comprise additional layers, for example adhesion layers, upper layers or elastic underlayers.

The photopolymerizable layers may be developable in aqueous or organic media, depending on the binder used. However, the advantages of the invention are particularly evident if the layer can be developed in organic media.

The element which is essential to the invention is the novel combination of at least two different types of IR-ablative layers A and B. These may be on the photopolymerizable layer, directly or also indirectly, i.e. separated by a thin interlayer, for example an adhesion or barrier layer. The IR-ablative layer is preferably applied directly to the photopolymerizable layer.

The IR-ablative layer A comprises at least one elastomeric binder and an IR absorber for laser radiation. Examples of elastomeric binders which can be employed are binders which can also be employed for the production of the photopolymerizable layer. It is possible to use, in particular, polymers comprising diene units, for example polybutadiene, polyisoprene or natural rubber.

It is particularly advantageous to use block copolymers having rigid polymer blocks comprising styrene, acrylonitrile or acrylate units and elastic blocks comprising diene polymers, for example butadiene or isoprene. Suitable are, for example, elastomeric three-block copolymers having styrene-isoprene-styrene or styrene-butadiene-styrene blocks, as described, for example, in DE-A 22 15 090. The three-block copolymers can be employed as the only elastomers or alternatively as a mixture with two-block copolymers, for example styrene-isoprene or styrene-butadiene two-block copolymers. Preference is given to SIS block copolymers. The diene units can also be fully or partially hydrogenated.

It is also possible to employ other elastomers, for example acrylate rubbers, elastomeric polyurethanes, for example polyether-polyurethanes or polyester-polyurethanes, silicone rubbers or elastomeric polyamides.

It is of course also possible to employ mixtures of two or more different elastomeric binders.

The amount of binders A in the IR-ablative layer A is generally from greater than 40% by weight to a maximum of 90% by weight, based on the amount of all constituents of the IR-ablative A layer, preferably from 45 to 80% by weight and very particularly preferably from 45 to 70% by weight.

The IR-ablative layer B comprises at least one self-decomposing binder and at least one IR-absorber for laser radiation.

The self-decomposing or self-oxidative binder is a binder which decomposes or depolymerizes very easily under the action of heat without melting. Corresponding pixels therefore have very steep edges, enabling very high resolutions to be achieved. Self-decomposing or self-oxidative binders which can be employed are binders which contain azide groups and very particularly preferably those which contain nitro or nitrate ester groups.

Examples of suitable binders include polyglycidyl azide, polyglycidyl nitrate or polyvinyl nitrate, polymers of nitro-substituted styrenes, for example polymers containing nitro-, dinitro- or trinitrostyrene groups. Polystyrene may furthermore also be nitro-substituted in the main chains. Further examples include polyacrylates and polymethacrylates, for example polymers containing 2,4-dinitrophenyl acrylates or p-nitrophenyl acrylate as monomeric units.

Particularly suitable self-decomposing binders are nitrate esters of cellulose or cellulose derivatives, for example cellulose ethers. Nitrate esters of this type are also known as nitrocellulose and are commercially available with various contents of nitrate ester groups (for example Wolff-Walsrode), the degree of esterification affecting not only the decomposition properties, but also the solubility properties of the nitrocellulose. The invention is preferably carried out using alcohol-soluble nitrocellulose grades. These are commercially available and usually have an N content of from 10.9 to 11.3%. However, it is also possible to employ other grades having a higher nitrogen content.

It is also possible to employ nitrate esters of cellulose ethers, for example methylcellulose, ethylcellulose and in particular 2-hydroxyethyl-, 2-hydroxypropyl- or carboxymethylcellulose. Nitrated carboxymethylcellulose can also be employed as Na salt, which increases the water solubility. It is of course also possible to employ mixtures of various self-decomposing binders.

The amount of self-decomposing binders in the IR-ablative layer B is generally greater than 40 to a maximum of 90% by weight, based on the amount of all constituents of the IR-ablative layer B, preferably from 45 to 80% by weight and very particularly preferably from 45 to 70% by weight.

Furthermore, both layers A and B comprise at least one absorber for laser radiation.

The absorber is a substance which is finely distributed in the layer. This should have the highest possible absorption between 750 and 20,000 nm. Suitable substances as absorber include IR-absorbent dyes, for example phthalocyanines and phthalocyanine derivatives, merocyanines or methine dyes, and strongly colored inorganic pigments, for example carbon black, graphite, iron oxides or chromium oxides. Preference is given to carbon black. Besides the function as IR absorber, carbon black equally ensures that the IR-ablative layer is opaque to actinic radiation, meaning that it is not absolutely necessary additionally to employ a UV-absorbent dye. It is preferred to employ finely divided particles in order to obtain the highest possible tinting strength and the most uniform layer possible. Preference is given to finely divided carbon black grades, for example Printex® U, Printex® L6, Special Black 4 or Special Black 250 from Degussa.

The amount of absorber for the laser radiation is usually from 1 to 59.9% by weight, based on the sum of all constituents of the layer, preferably from 10 to 50% by weight and particularly preferably from 25 to 50% by weight.

The IR-ablative layers A and B may additionally also comprise additional auxiliaries or additives. Examples of auxiliaries of this type are dispersion aids for pigments, fillers, plasticizers or coating aids. Auxiliaries or additives of this type are selected by the person skilled in the art depending on the desired properties of the layer, provided that they do not adversely affect the properties of the layer. Suitable dispersion aids for carbon blacks are, in particular, polyoxyalkylene derivatives, for example Solperse grades (Avecia) or block copolymers, such as Disperbyk grades (Byk). It is also possible to employ UV absorbers as auxiliaries. This is usually not absolutely necessary in the case of the use of carbon black as absorber, but may occasionally be advantageous. On use of IR dyes as absorber, the use of additional UV absorbers is frequently unavoidable, although not absolutely necessary in each case. In general, the amount of all additives and auxiliaries should not exceed 20% by weight, preferably 10% by weight and very particularly preferably 5% by weight, based on the sum of all constituents of the IR-ablative layer.

In addition to the principal binder the IR-ablative layers A and B may, moreover comprise at least one further binder of a different chemical nature, which will be referred to below as the secondary binder. It is also possible to employ a plurality of different binders as secondary binders. The amount of the secondary binder is less than the amount of the principal binder. The amount of a secondary binder of this type is usually from 0 to 40% by weight, preferably from 0 to 20% by weight and particularly preferably from 0 to 10% by weight, based on all constituents of the IR-ablative layer.

The secondary binder is selected by the person skilled in the art depending on the desired properties of the IR-ablative layer, provided that the properties of the layer are not adversely affected by the secondary binder.

The sequence of layers A and B is not essential to the invention. Layer A may be arranged as the lowermost layer, i.e. directly on the photopolymerizable printing layer, and layer B on top. However, the reverse layer sequence, namely B-A, can also be selected particularly advantageously, with the layer comprising the self-decomposing binder being embedded between the elastomeric layer and the photopolymerizable layer. It is also possible for a plurality of layers A and B to be present. Thus, for example, a sandwich layer sequence A-B-A may be present, with the layer comprising self-oxidative binder B being embedded between two layers A.

Besides layers A and B, the flexographic printing element may also comprise further, preferably IR-ablative layers of a different composition, for example layers C. The layer sequence A-B-C, B-A-C or C-B-A, for example, is then possible. Layers C of this type may have a similar structure to A and B comprising binder and IR absorber, but they may also have a different composition. The layers C are preferably themselves IR-ablative. However, the minimum requirement is that additional layers of this type must not interfere with the ablation of A and B, i.e. must at least be removable together therewith. All layers should furthermore be soluble or at least swellable in the developer for the photopolymerizable layer.

The sequence of layers A and B and any further layers is essentially opaque to actinic radiation. In general, the optical density of all IR-ablative layers together in the actinic spectral region is at least 2.5, preferably at least 3.0, and very particularly preferably 3.5. Said optical density is in each case measured as the wavelength or in the wavelength range employed for the exposure of the element during full-area irradiation. It is entirely possible for the optical density of the individual layers to be different and is generally less than 2.5 considered individually in each case. The properties of the entire layer system are crucial.

The total thickness of all IR-ablative layers should be as low as possible in order that the layer system can be removed as efficiently as possible by means of laser radiation. The total thickness of the layer sequence is restricted at the lower end inasmuch as the layer sequence must have an optical density of at least 2.5. In general, a thickness of from 1 to 10 μm is appropriate, without the invention being restricted to this range. The thickness of the individual layers from which the layer system is built up is determined by the person skilled in the art depending on the desired properties. In general, however, none of the individual layers has a thickness less than 20% of the total thickness of the layer system, although the invention is not restricted thereto. In the case of two layers A and B, a thickness ratio of from 60:40 to 40:60 has proven successful.

It is advisable to protect the IR-ablative flexographic printing element according to the invention against damage during transport, storage and handling by a flexible protective film, although a protective film of this type is not absolutely necessary.

The photosensitive flexographic printing elements according to the invention can be produced by firstly applying the photopolymerizable layer and optionally further layers to the support, and subsequently applying the IR-ablative layers A and B and, if desired, other layers, one after the other, for example by casting or lamination. To this end, firstly all constituents of each layer are dissolved or dispersed in a suitable solvent or solvent mixture with vigorous mixing. Solutions or dispersions of this type can then be applied directly to the photopolymerizable element layer by layer and the solvent evaporated. However, the solutions can also be cast onto a support film, for example a PET film, layer by layer and the respective solvent evaporated. The coated support is then laminated onto the photopolymerizable layer under pressure and/or the influence of heat. The support for the IR-ablative layers then functions as protective film for the entire photopolymerizable printing element. Of course, with this technique, the topmost layer must be cast first, followed by the other layers.

The photosensitive printing elements according to the invention with a plurality of IR-ablative layers A and B are employed for the production of flexographic printing plates. If present, the protective film is firstly removed. The IR-ablative layer is then irradiated imagewise using a suitable laser in order to obtain a photographic mask. Examples of suitable IR lasers include Nd/YAG lasers (1064 nm) and diode lasers (for example 830 nm). Suitable laser systems for computer-to-plate technology are commercially available, for example the OmniSetter® diode laser system (Misomex, wavelength 830 nm; working width 1800 mm) or the digilas® Nd/YAG laser system (Ohio-Schepers), each of which comprises a cylindrical drum, onto which the flexographic printing element with IR-ablative layer is mounted. The drum is subsequently set in rotation, and the element is imaged by means of the laser beam.

After writing the mask, the photosensitive element is exposed over the entire area to actinic light through the mask. This can advantageously be carried out directly on the laser cylinder. However, the plate can also be taken off and exposed in a conventional flat-bed exposure apparatus—in air, under nitrogen or in vacuo. During the exposure step, the layer is photochemically crosslinked in the areas uncovered by IR ablation in the preceding process step, while the areas still covered remain uncrosslinked.

In a further process step, the exposed element is developed. The development can in principle be carried out in commercially available developer apparatuses using commercially available wash-out agents for flexographic printing plates, for example nylosolv® or Optisol®. During the development, the unexposed areas of the photopolymerizable layer and the residues of the IR-ablative layer are removed. It is preferred to employ only a single wash-out agent for this process step. However, it is also possible firstly to remove the residues of the IR-ablative layer using a wash-out agent and subsequently to develop the plate in a second wash-out agent. After the development, the resultant flexographic printing plates are dried in a known manner. The process may comprise further process steps, for example detackifying with UV-C or Br₂.

The flexographic printing elements according to the invention with a plurality of IR-ablative layers have a number of advantages:

Although the sensitivity to laser radiation does not reach that of pure nitrocellulose layers, it is nevertheless higher than that of commercially available plates. The combination of an elastomeric layer A with a layer comprising self-decomposing binder B, such as, in particular, nitrocellulose, means that firstly a very sensitive flexographic printing element is obtained which nevertheless has surprising high elasticity. Flexographic printing plates of this type can easily be laid around the drums of laser exposure units without the layer tearing or wrinkling. The amount of plasticizer in the nitrocellulose layer can be significantly reduced compared with pure nitrocellulose plates. The advantages are particularly clear if the IR-ablative layer comprising the elastomeric binder is located at the uppermost point. The layer surface is tack-free and the protective or cover film adhesion is low, enabling the protective film to be removed without problems. The adhesion to the photopolymerizable layer is high, so that the IR-ablative layer remains adhering to the photopolymerizable layer even on rapid and unintentional removal of the protective film. The layers can be washed off using conventional organic wash-out agents, such as nylosolv®.

The following examples are intended to explain the invention by way of example.

General procedure for the preparation of a dispersion of IR absorber and binder.

A dispersion aid (Solperse 20 000) is pre-dissolved in the solvent mixture. The binder(s) A and any further additives are subsequently added and dissolved with stirring. The carbon black is then added slowly and dispersed in for 15 minutes at a dissolver speed of 5000 rpm. The resultant mixture is ground for 1 hour in a laboratory stirred ball mill. The dispersion has a solids content of 10% by weight, based on the sum of all constituents.

A dispersion of the solid constituents of layer B is obtained in a similar manner in a suitable solvent.

Firstly, either dispersion A or dispersion B is coated onto a PET film using a laboratory knife coater and dried at 60° C. for 10 minutes. The remaining dispersion is then introduced and dried under the same conditions.

The optical density of a film of this type in the spectral region of actinic light is from 3.0 to 3.5.

The protective film and substrate layer are removed from a commercial flexographic printing plate of the FAH 254 type (BASF), so that the surface of the photopolymerizable layer is uncovered. The PET film coated with the IR-ablative layer system is dry-laminated onto the surface of the photopolymerizable layer so that the IR-ablative layer system and the photopolymerizable layer are bonded to one another. The PET film forms the protective film. The plate is stored for 1 week at room temperature.

### EXAMPLES 1

A dispersion B for the IR-ablative layer B was prepared as described from 35% by weight of carbon black, 3% by weight of dispersion aid (Solperse 20000), 52% by weight of nitrocellulose (type A 400, Wolff-Walsrode) and 10% by weight of plasticizer (Plasthall 41 41 (CP Hall)) (or data based on the total amount of all constituents of the dried layer) in a solvent mixture comprising toluene, propanol, benzyl alcohol and ethyl acetate (solids content 10% by weight).

A dispersion A for the IR-ablative layer A was prepared as described from 35% by weight of carbon black, 3% by weight of dispersion aid (Solperse 20000), 62% by weight of an elastomeric binder (elastomeric polyether-polyurethane), Surkofilm 72 S, Mitchanol) (or data based on the total amount of all constituents of the dried layer) in a solvent mixture comprising ethanol, ethyl acetate and benzyl alcohol (solids content 10% by weight). The starting materials and amounts are also shown in Table 1.

Firstly dispersion A was cast onto the PET film and dried, then dispersion B. The layer system obtained was laminated onto the flexographic printing plate as described. The thickness of the layer system was about 2.5 μm; the two part-layers were of equal thickness.

The cover film adhesion, the substrate adhesion, the elasticity and the tack of the IR-ablative layer of the resultant plates were determined. The measurement methods for the measurement parameters are shown in Table 3, and the results are shown in Table 2.

### EXAMPLES 2 AND 3

The procedure was as in Example 1, but different elastomeric binders were employed.

### COMPARATIVE EXAMPLE C1

The procedure was as in Example 1, but layer A was omitted, and only the nitrocellulose-containing layer B was cast. The thickness of layer B was about 2.5 μm.

### COMPARATIVE EXAMPLE C2

The procedure was as in Example C1, but the alcohol-soluble nitrocellulose type A 400 was replaced by the ester-soluble type E 900 (each Wolff-Walsrode).

Laser Imaging, Conversion into a Flexographic Printing Plate, General Procedure

The PET protective film is removed from the flexographic printing element with IR-ablative layer system, and the plate is mounted onto the rotatable drum (diameter: 0.25 m) of an Nd/YAG laser system (Schepers, Ohio, digilas®). The drum is accelerated to 1600 rpm. The laser moves forward by 10 μm per drum rotation.

In a first experiment, firstly the minimum laser power necessary for complete removal of the IR-ablative layer at the points at which it is hit by the laser beam is determined for said drum speed and laser advance for each plate. The requisite laser power can be used to determine the sensitivity of the plate in J/m², i.e. the minimum energy per unit area which is necessary to remove the layer. The sensitivity is higher the lower the minimum energy.

In a further experiment, each plate is imaged digitally with the laser power determined. The photopolymerizable flexographic printing element obtained with digital mask is irradiated for 15 minutes with actinic light in a conventional manner and subsequently developed in a conventional manner in a brush washer using the commercial (organic) wash-out agent nylosolv® II. After the development, the plate is dried at 60° C. for 2 hours, irradiated with UV-C light for detackifying and finally post-crosslinked for 10 minutes with actinic light.

### EXAMPLES 1-3 AND COMPARATIVE EXAMPLES C1-C2

In each case, the flexographic printing elements produced were employed. The laser power determined in each case and the sensitivity are shown in Table 2. The ability of the IR-ablative layer to be washed off or removed in the wash-out agent was also determined. The results are shown in Table 2, and the measurement method is shown in Table 3.

### COMPARATIVE EXAMPLES C3-C6

The mechanical properties, the sensitivity and the processing properties of 4 commercially available flexographic printing elements with IR-ablative layer were determined as outlined above. The results are likewise shown in Table 2.

TABLE 1
Compositions of the IR-ablative layers

| No. | Layer A | Layer B | Sequence |
|---|---|---|---|
| 1 | 62% of polyether-polyurethane (Surkofilm 72 S) | 52% of nitrocellulose (A 400), 10% of plasticizer, 35% of | B-A |
| | 35% of carbon black, 3% of Solperse | carbon black, 3% of Solperse | |
| 2 | 62% of SBS polymer (Kraton ® 1101) | 52% of nitrocellulose (A 400), 10% of plasticizer, 35% of | B-A |
| | 35% of carbon black, 3% of Solperse | carbon black, 3% of Solperse | |
| 3 | 62% of elastomeric polyamide (Makromelt ® 6900) | 52% of nitrocellulose (A 400), 10% of plasticizer, 35% of | B-A |
| | 35% of carbon black, 3% of Solperse | carbon black, 3% of Solperse | |
| C1 | No layer A | 52% of nitrocellulose (A 400), 10% of plasticizer, 35% of | Only one layer |
| | | carbon black, 3% of Solperse | |
| C2 | No layer A | 52% of nitrocellulose (A E 950), 10% of plasticizer, 35% of | Only one layer |
| | | carbon black, 3% of Solperse | |

TABLE 2
Test results

| | | Laser | Sensi- | | | | | Ability to be |
|---|---|---|---|---|---|---|---|---|
| | | power | tivity | Tack- | Substrate | Cover film | | washed off in |
| No. | Product | [W] | [J/cm²] | free | adhesion | adhesion | Elasticity | nylosolv II |
| 1 | Layer A: Polyether polyurethane Surkofilm 72 S | 3.0 | 1.5 | + | + | + | + | + |
| | Layer B: Nitrocellulose/plasticizer | | | | | | | |
| 2 | Layer A: SBS rubber | 3.2 | 1.6 | + | + | + | + | + |
| | Layer B: Nitrocellulose/plasticizer | | | | | | | |
| 3 | Layer A: Polyamide | 3.2 | 1.6 | + | + | + | (+) | + |
| | Layer B: Nitrocellulose/plasticizer | | | | | | | |
| V 1 | Only one layer made of NC A 400/ | 1.7 | 0.8 | + | + | − | (−) | + |
| | plasticizer | | | | | | | |
| V 2 | Only one layer made of NC E 950/ | 1.8 | 0.8 | + | + | (−) | (+) | (+) |
| | plasticizer | | | | | | | |
| | Commercial product | | | | | | | |
| V 3 | Dupont Cyrel ® DPH | 5.0 | 2.4 | + | (+) | + | (+) | + |
| V 4 | Asahi AFP ® XDI | 4.3 | 2.1 | + | + | + | (+) | + |
| V 5 | BASF digiflex ® I | 3.7 | 1.8 | + | (+) | + | (+) | − |
| V 6 | Polyfibron Flexlight ® CBU | 6.3 | 3.1 | + | + | + | (+) | + |

Layers each contain 35% of carbon black

TABLE 3
Explanations of the assessments in Table 1

| Property/Assessment | + | (+) | (−) | − |
|---|---|---|---|---|
| Tack-free | Fully tack-free | Low tack | Slightly tacky | Highly tacky |
| Substrate adhesion | Very strong: | Substrate difficult to | Substrate easy to remove: | Weak, substrate very easy to |
| | substrate cannot be | remove: | 0.3-2. | remove 0.1-0.2 |
| | removed: >30 and very | 2-5 | | |
| | difficult to remove: 5-30 | | | |
| Cover film adhesion | Weak | Normal | Strong | Too strong/very difficult to |
| | 0.01-0.08 | 0.09-0.19 | 0.2-0.5 | remove: >0.5 |
| Elasticity | Does not tear and does not | Does not tear and does not | Tears and wrinkles on | Tears easily and wrinkles on |
| | wrinkle even on severe | wrinkle on external | external and internal | external and internal |
| | bending inward and | bending, but does on | bending | bending |
| | outward | internal bending | | |
| Ability to be washed out in | Removed after 1st brush | Removed after 2nd brush | Removed after 3rd brush | Remains on the |
| nylosolv ® II | | | | flexographic plate during |
| | | | | the entire washing process |

Values for substrate adhesion and cover film adhesion in N/4 cm: N/4 cm:
Measured on a 4 cm wide strip of the printing plate in a Zwick 1435 universal testing machine for stress/strain experiments.
Ability to be washed out: during standard wash-out operation in a nyloflex Combi L F II wash-out unit

The examples and comparative examples show that flexographic printing elements are obtained which satisfy the requirements in an excellent manner. The flexographic printing elements according to the invention comprising at least two IR-ablative layers furthermore have the advantage that alcohol-soluble nitrocellulose grades, which are also very readily soluble in customary developers for flexographic printing plates, can also be employed here. Owing to their high top film adhesion, the use of grades of this type was not possible in the case of the known single-layered systems. The invention opens up the possibility of also employing grades of this type.

We claim:

1. A photosensitive flexographic printing element for the production of flexographic printing plates for digital imaging by means of lasers, comprising at least
a dimensionally stable support,
at least one photopolymerizable layer, at least comprising an elastomeric binder, a polymerizable compound and a photoinitiator or photoinitiator system,
at least two laser-ablatable layers A and B, each comprising at least one binder and also an IR absorber for laser radiation, and
optionally a removable, flexible protective film
wherein the at least one binder of layer A is an elastomeric binder and the at least one binder of layer B is a self-decomposing binder, and the optical density of the entire layer sequence of IR-ablative layers in the actinic spectral region is at least 2.5.

2. A photosensitive flexographic printing element as claimed in claim 1, wherein the self-decomposing binder of layer B contains nitro or nitrate ester groups.

3. A photosensitive flexographic printing element as claimed in claim 2, wherein the binder containing the nitro and/or nitrate ester groups is a cellulose or cellulose ether nitrate ester.

4. A photosensitive flexographic printing element as claimed in one of claims 1 to 3, wherein the elastomeric binder is a binder comprising diene units.

5. A photosensitive flexographic printing element as claimed in one of claims 1 to 4, wherein the IR absorber is carbon black.

6. A photosensitive flexographic printing element as claimed in one of claims 1 to 5, wherein the flexographic printing element has further IR-ablative layers.

7. A process for the production of a flexographic printing plate in which the starting material employed is a photosensitive flexographic printing element as claimed in one of claims 1-6, comprising the following steps:
(a) removal of the removable, flexible protective film, if present,
(b) writing of a mask into the layer system comprising IR-ablative layers by means of an IR laser,
(c) full area exposure of the photosensitive element to actinic light through the mask formed in step (b),
(d) treatment of the intermediate formed in (c) with at least one developer solution, during which the residues of the IR-ablative layers which have not been removed in step (b) are removed and the exposed photopolymerizable layer is developed.

8. A process as claimed in claim 7, wherein step (b) is carried out using a laser apparatus having a rotating drum, and the flexographic printing element is mounted on this drum for ablation.
